(19) United States
(12) Patent Application Publication
(10) Pub. No.: US 2015/0052742 A1
(43) Pub. Date: Feb. 26, 2015

(54) CIRCUIT BOARD AND MANUFACTURING METHOD THEREOF

(71) Applicant: BOARDTEK ELECTRONICS CORPORATION, Taoyuan County (TW)

(72) Inventors: CHIEN-CHENG LEE, TAOYUAN COUNTY (TW); Chung-Hsing Liao, Taoyuan County (TW)

(73) Assignee: BOARDTEK ELECTRONICS CORPORATION, Taoyuan County (TW)

(21) Appl. No.: 13/973,012

(22) Filed: Aug. 22, 2013

(51) Int. Cl. H05K 1/02

(52) U.S. Cl. CPC H05K 1/0212
USPC 29/829; 174/252

(57) ABSTRACT

A circuit board structure manufacturing method includes the following steps. A circuit substrate is provided including an insulating layer, a first metal layer, and a second metal layer. The insulating layer is disposed between the first metal layer and the second metal layer. The first metal layer has a first cavity. The insulating layer has a second cavity and a provisional region. A width of the first cavity is larger than a width of the second cavity. The provisional region is defined between a sidewall of the first metal layer defining the first cavity and another sidewall of the first metal layer defining the second cavity. A first masking layer is formed to cover the first metal layer and provisional region. The second cavity is exposed from the first masking layer. A heat-dissipating metal member is formed in the second cavity. Furthermore, the first masking layer is removed.

### BACKGROUND OF THE INVENTION

1. Field of the Invention

The instant disclosure relates to a circuit board structure; in particular, to a manufacturing method of the circuit board structure.

2. Description of Related Art

Under the trend of miniaturization, the overall module packaging of the common electronic products, such as mobile phones or notebook computers, becomes denser. Thus, functionalities of the electronic products are becoming more versatile, rendering larger power consumption which leads to enormous amount of heat generated and the overall temperature to increase. In order to lower the temperature due to overheating, the circuit board tends to be designed with copper (e.g. copper rod or column) thereon as a way to dissipate heat for the electronic components.

Typically, in the conventional method of electroplating a heat dissipating copper column, a two-sided copper-clad laminate of the circuit board is usually drilled through, and the sidewalls of the drilled cobalt holes are electroplated with a layer of copper. However, since copper ions tend to aggregate near the edges of the traces, sidewalls of openings or wall junctions between sidewalls of openings and heat dissipating copper columns, excess aggregation of copper ions tends to form copper lumps at the wall junctions.

To address the above issues, the inventor strives via associated experience and research to present the instant disclosure, which can effectively improve the limitation described above.

### SUMMARY OF THE INVENTION

The object of the instant disclosure is to provide a manufacturing method for a circuit board structure which has heat-dissipating metal columns that can facilitate heat dissipation of the circuit board structure.

In order to achieve the aforementioned objects, according to an embodiment of the instant disclosure, a circuit board structure is provided which includes a circuit substrate and at least one heat-dissipating metal member. The circuit substrate includes an insulating layer, a first metal layer, and a second metal layer. The insulating layer is disposed between the first metal layer and the second metal layer. The first metal layer has portions defining a first cavity. The insulating layer has portions defining a second cavity. The second cavity is exposed through the second metal layer. The first cavity has a width larger than a width of the second cavity and the heat-dissipating metal member is formed in the second cavity.

In summary, the embodiment of the instant disclosure provides a manufacturing method for a circuit board structure. The first cavity has a width larger than a width of the second cavity. The provisional region is defined by a sidewall of the first metal layer defining the first cavity and a sidewall of the insulating layer defining the second cavity. The first masking layer is formed to cover the first metal layer and the provisional region such that metal ions are less susceptible to attach near edges of the second cavity during the formation of the heat-dissipating metal member via electroplating. As a result, the heat-dissipating metal member is fully formed via electroplating.

In order to further understand the instant disclosure, the following embodiments and illustrations are provided. However, the detailed description and drawings are merely illustrative of the disclosure, rather than limiting the scope being defined by the appended claims and equivalents thereof.

### BRIEF DESCRIPTION OF THE DRAWINGS

FIG. 1A to 1F are schematic diagrams illustrating the steps of forming a circuit board structure in accordance with a circuit board structure manufacturing method of the instant disclosure;

FIG. 2 is a schematic diagram of the circuit board structure manufacturing method in accordance with a first embodiment of the instant disclosure; and

FIG. 3 is a schematic diagram of the circuit board structure manufacturing method in accordance with a second embodiment of the instant disclosure.

### DETAILED DESCRIPTION OF THE PREFERRED EMBODIMENTS

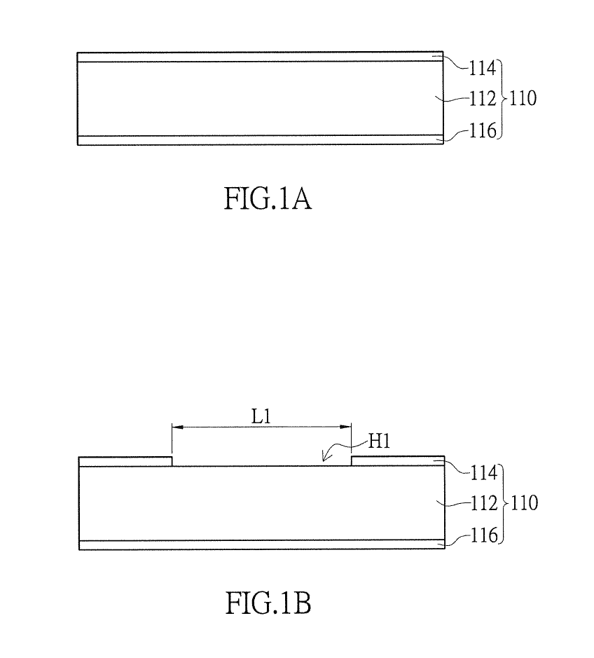

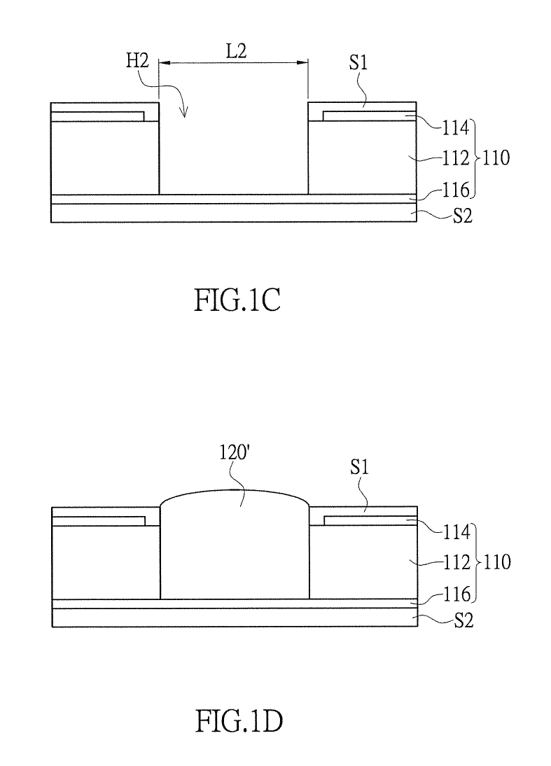

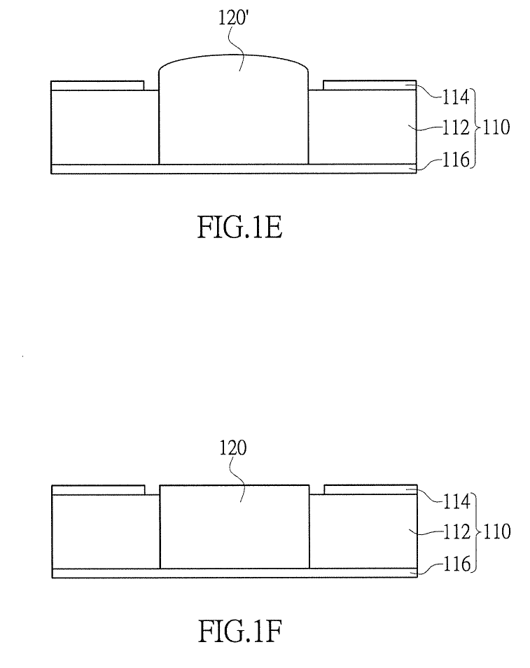

FIG. 1A to 1F are schematic diagrams illustrating the steps of forming a circuit board structure in accordance with a circuit board structure manufacturing method of the instant disclosure. Please refer to FIGS. 1A to 1F.

Please refer to FIG. 1A. Firstly, a circuit substrate 110, which includes an insulating layer 112, a first metal layer 114 and a second metal layer 116, is provided. The insulating layer 112 is sandwiched between the first metal layer 114 and the second metal layer 116. In the instant embodiment, the circuit substrate 110 is a two-sided metal-clad laminate. The first metal layer 114 and second metal layer 116 are disposed on opposite sides of the insulating layer 112. Generally, the first, second metal layers 114, 116 are made of metal foils (or thin films) such as copper foils. However, the circuit substrate 110 can also be a ready-made multi-layered circuit board, and is not limited hereto.

Please refer to FIG. 1B. A pattern is developed on the first metal layer 114 such that a first cavity H1 is formed thereon. Specifically, the first cavity H1 is formed by removing portions of the first metal layer 114 via photolithography etching. As a result, portions of the insulating layer 112 are exposed via the first cavity H1. In addition, the first cavity H1 has a width L1.

Please refer to FIG. 1C. A pattern is developed on the insulating layer to form the second cavity passing through the second metal layer. Specifically, the second cavity H2 is formed by removing materials from the insulating layer 112 through the first cavity H1. Notably, the second metal layer 116 is exposed via the second cavity 112. The width L1 of the first cavity H1 is larger than a width L2 of the second cavity H2. The second cavity H2 can be formed by laser drilling or milling. Specifically, the second cavity H2 is formed by downwardly eroding the insulating layer 112 through the first cavity H1, as if a cavity extending from the first cavity H1, via laser ablation. Portions of the insulating layer 112 which are exposed through the first cavity H1 can be milled to form the second cavity H2. Alternatively, the second cavity H2 can also be first milled to remove portions of the insulating layer 112, then further removing other portions of the insulating layer 112 via laser ablation. Successively, remaining insulating layer 112 is removed, which are left on a surface of the second metal layer 116, via chemicals.

The insulating layer 112 has a provisional region M1 which is defined by a sidewall of the first metal layer 114 defining the first cavity H1 and a sidewall of the insulating layer 112 defining the second cavity H2. Specifically, the provisional region M1 is defined as the spaced apart region above the insulating layer 112, and between the sidewall of the first metal layer 114 defining the first cavity H1 and the sidewall of the insulating layer 112 defining the second cavity H2. In other words, the first metal layer 114 does not completely covers the insulating layer 112.

A first masking layer S1 is formed to cover the first metal layer 114 and the provisional region M1, and a second masking layer S2 is formed to cover the second metal layer 116. Specifically, the first masking layer S1 and the second masking layer S2 can be anti-etching dry film, photoresist or other insulating materials. The first masking layer S1 covers the first metal layer 114 and the provisional region M1, and the first masking layer S1 exposes the second cavity H2. The second masking layer S2 covers the outer surface of the second metal layer 116. Notably, the first masking layer S1 and the second masking layer S2 expose only the second metal layer 116 via the second cavity H2. The instant disclosure does not limit the sequence of the procedures or steps to simultaneously or sequentially forming the first, second masking layers S1, S2, and the first, second cavities H1, H2.

Moreover, in another embodiment of the instant disclosure, the circuit board structure 100 manufacturing method can also include forming the first masking layer S1 to cover the first metal layer 114 and the first cavity H1 before the second cavity H2 is formed by extending the first cavity H1 through the insulating layer 112. Moreover, the second masking layer S2 is formed to cover the second metal layer 116. Specifically, a pattern is developed on the first metal layer 114, after the first metal layer 114 is formed with a first cavity H1, the first masking layer S1 is formed to cover the first metal layer 114 and the first cavity H1 while exposing the insulating layer 112. The second masking layer S2 is formed on a surface of the second metal layer 116. Then, the second cavity H2 is formed through the first masking layer S1 and the insulating layer 112.

Furthermore, in another embodiment of the instant disclosure, the circuit substrate 110 can also be formed by the build up process. Specifically, first providing the insulating layer 112. The second cavity H2 is formed on the insulating layer 112. Thereafter, two opposite sides of the insulating layer 112 are respectively covered by the first metal layer 114 and the second metal layer 116, in which the first metal layer 114 already has the first cavity H1 formed thereon. Namely, the first metal layer 114 has not yet covered the provisional region M1. After high temperature lamination, the circuit substrate 110 is formed.

Please refer to FIG. 1D. The first masking layer S2 is used as a mask. A heat-dissipating metal member 120′ is formed in the second cavity H2 via electroplating. Specifically, copper is plated to fill in the second cavity H2 via electroplating in order to form the solid heat-dissipating metal member 120′. Generally in forming the heat-dissipating metal member via conventional electroplating methods, metal ions (e.g. copper ions) are susceptible to aggregate near edges of metal layers, for example, near edges of the traces or near edges of openings of the metal layers. In turn excess metal (copper nodule) is susceptible to form near edges of the metal layers, and as a result, product yield is decreased.

However, since the first masking layer S2 covers the first metal layer 114 and the provisional region M1, edges of the second cavity H2 is less likely to aggregate metal ions which in turn forms metal nodules during the formation of the heat-dissipating metal member 120′ via electroplating. Thus, the heat-dissipating metal member 120′ can be fully formed. Moreover, the second masking layer S2 covers a surface of the second metal layer 116 to prevent metal ions from attaching onto the second metal layer 116.

Please refer to FIG. 1E. The first and second masking layers S1, S2 are removed. Since the first, second masking layers S1, S2 can be anti-etching dry film or photoresist, both layers S1, S1 can be removed by an aqueous solution of sodium hydroxide.

Please further refer to FIG. 1F. In order to facilitate installing of electronic components C1 onto a leveled top portion of the heat-dissipating metal member 120′, the circuit board structure 100 manufacturing method also includes abrasively treating. Specifically, the top portion of the heat-dissipating metal member 120′ is abrasively treated via belt grinding machines to form a leveled top portion of heat-dissipating metal member 120′. As a result, electronic components C1 can be easily installed onto the top portion of the heat-dissipating metal member 120′. Notably, in order to accommodate various sizes and designs of electronic components C1, the heat-dissipating metal member 120′ may have various heights. In other words, the top portion of the heat-dissipating metal member 120′ can be higher or lower than a top surface of the first metal layer 114. In the instant embodiment, the top portion of the heat-dissipating metal member 120′ is abrasively treated to be substantially leveled with the top surface of the first metal layer 114. However, in a second embodiment, the top portion of the heat-dissipating metal member 120′ can be abrasively treated to be lower than the first metal layer 114, which is denoted as the heat-dissipating metal member 220.

Furthermore, traces can be etched thereafter. Surfaces of the first metal layer 114 and the second metal layer 116 are etched to respectively form a first circuit layer 114′ and a second circuit layer 116′. However, the etching process is not limited to the examples provided herein.

Thereafter, the electronic components can be installed via wired bonding, flip clip or other methods to electrically connect the first metal layer 114 and be disposed onto the heat-dissipating metal member 120. In addition, the heat-dissipating metal member 120 can dissipate heat to the environment such that normal operations of the electronic components are not affected by overheating.

Please refer again to FIG. 1F as a schematic diagram of the circuit board structure in accordance with the instant embodiment of the instant disclosure. The circuit board structure 100 includes the circuit substrate 110 and the heat-dissipating structure 120. The circuit substrate 110 includes the first metal layer 114, the second metal layer 116, and the insulating layer 112 which is sandwiched between the first and second metal layers 114, 116. The first metal layer 114 has the first cavity H1, and the insulating layer 112 has the second cavity H2. The heat-dissipating metal member 120 is disposed in the second cavity H2.

The circuit substrate 110 serves as a carrier of various electronic components. In general, the insulating layer 112 of the circuit substrate 110 has the first, second metal layers 112, 114 installed thereon, and the first, second metal layers 112, 114 includes bonding pads and traces. In practice, the first, second metal layers 112, 114 may have various configurations depending on the required electrical connections in which the product demands.

In the instant embodiment, the circuit substrate 110 is a two-sided circuit board structure. The insulating layer 112, and the first, second metal layers 112, 114 cooperatively form the circuit substrate 110. However, in another embodiment, the circuit substrate 110 can be a multi-layer circuit board structure. The circuit substrate 110 may include two or more insulating layers 112 which are located between the first and second metal layers 114, 116. Notably, the circuit substrate 110 can also be a two-sided circuit board structure or a multi-layer circuit board structure, but is not limited herein.

The insulating layer 112 is positioned between the first and second metal layers 114, 116, and the first metal layer 114 has the first cavity H1, the insulating layer 112 has the second cavity H2. Notably, the second cavity H2 is formed by extending the first cavity H1 through the insulating layer 112. In other words, the first and second cavities H1, H2 are concentric. The first cavity width L1 is larger than the second cavity width L2 such that the insulating layer 112 is exposed through the first cavity H1, and the second metal layer 116 is exposed through the second cavity H2.

Notably, the insulating layer 112 is generally formed with pre-impregnated (pre-preg) materials. The pre-preg layer can be categorized as glass fiber, carbon fiber, or epoxy resin type of pre-preg according to the type of enhancing materials. However, the insulating layer 112 can be made of flexible substrate materials. In other words, the insulating layer 112 is substantially made of polyester (PET) or polyimide (PI) and excludes glass fibers, carbon fibers, etc. However, the materials of the insulating layer 112 are not limited herein.

The heat-dissipating metal member 120 is installed in the second cavity H2, and connected to the second metal layer 116 so that electronic components can be installed on the heat-dissipating metal member 120. The heat-dissipating metal member 120 dissipates heat to the environment such that normal operations of the electronic components are not affected by overheating.

Notably, in order to accommodate various sizes and designs of electronic components, the heat-dissipating metal member 120 may have various heights. In other words, the top portion of the heat-dissipating metal member 120 can be higher than, lower than, or leveled with a top surface of the first metal layer 114.

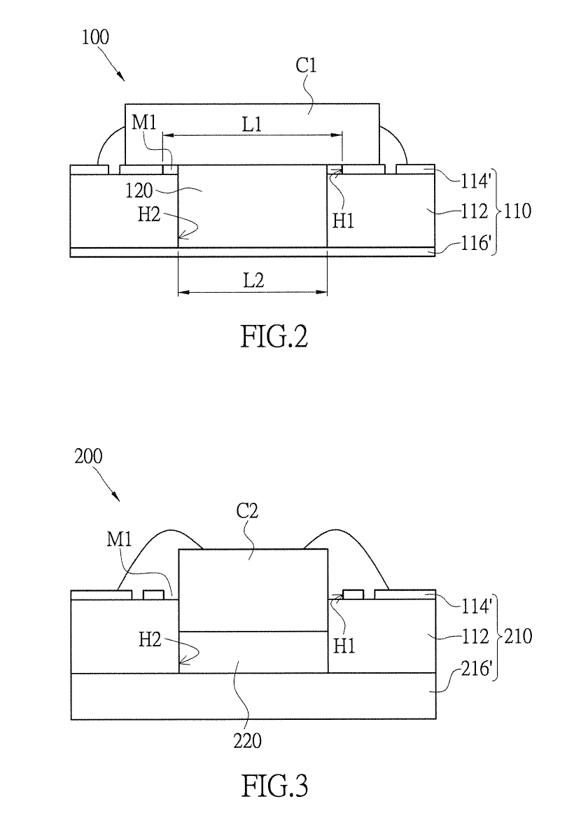

FIG. 2 is a schematic diagram of the circuit board structure manufacturing method in accordance with a first embodiment of the instant disclosure. Please refer to FIG. 2. In the instant embodiment, a top surface of the heat-dissipating metal member 120 is substantially leveled with a top surface of the first metal layer 114, and the electronic component C1 is installed on the heat-dissipating metal member 120. Accordingly, heat generated by electronic components C1 can be transferred to the environment via the heat-dissipating metal member 120. Notably, the electronic component C1 can be electrically connected to the first circuit layer 114′ via wire bonding, flip chip or other methods. The first and second circuit layers 114′, 116′ can be respectively formed by etching the first and second metal layers 114, 116. In addition, in another embodiment, the first and second metal layers 114, 116 can also respectively be the first and second circuit layers 114′, 116′. The electronic component C1 is installed on and thermally coupled to the heat-dissipating metal member 120.

FIG. 3 is a schematic diagram of the circuit board structure manufacturing method in accordance with a second embodiment of the instant disclosure. The structure and the effect of the circuit board structure 200 of the second embodiment is substantially the same as the circuit board structure 100 of the first embodiment. For example, the circuit board structures 200, 100 both include insulating layer. The following discloses the differences between the two circuit board structures 200, 100.

Please refer to FIG. 3, the circuit board structure 200 of the second embodiment includes the first circuit layer 114′, the second circuit layer 216′, and the insulating layer 112 which is sandwiched between the first circuit layer 114′ and the second circuit layer 216′. The first circuit layer 114′ has the first cavity H1, and insulating layer 112 has the second cavity H2. The heat-dissipating metal member 220 is installed in the second cavity H2. The electronic component C2 is disposed in the second cavity H2 and above the heat-dissipating metal member 220. The electronic component C2 and the first circuit layer 114′ is electrically connected and thermally coupled to the heat-dissipating metal member 220. The first circuit layer 114′ is formed by etching the first metal layer 114. Moreover, in another embodiment, the first metal layer 114 and the second metal layer 216 can be the first circuit layer 114′, and the second circuit layer 216′. Notably, in order to increase current carrying capacity of the circuit board structure 200, the second metal layer 216 is a thick copper layer. However, the thickness of the second metal layer 216 is not limited herein.

In the instant embodiment, a top surface of the heat-dissipating metal member 220 is substantially leveled with a top surface of the first metal layer 114 but is not limited herein. The electronic component C2 is installed on the heat-dissipating metal member 220. Accordingly, heat generated by the electronic components C2 can be transferred to the environment via the heat-dissipating metal member 220.

In summary, the instant embodiment provides circuit board structures and the manufacturing method of the same. The first cavity width of the circuit board structure is larger than the second cavity width. The provisional region is defined by a sidewall of the first metal layer defining the first cavity and a sidewall of the insulating layer defining the second cavity. The first masking layer covers the first metal layer and the provisional region such that metal ions are less susceptible to form metal nodules near edges of the second cavity during the formation of the heat-dissipating metal member via electroplating. As a result, the heat-dissipating metal member is fully formed via electroplating.

The figures and descriptions supra set forth illustrated the preferred embodiments of the instant disclosure; however, the characteristics of the instant disclosure are by no means restricted thereto. All changes, alternations, combinations or modifications conveniently considered by those skilled in the art are deemed to be encompassed within the scope of the instant disclosure delineated by the following claims.

What is claimed is:

1. A circuit board structure manufacturing method comprising the steps of:
providing a circuit substrate, the circuit board comprising:
an insulating layer;
a first metal layer; and
a second metal layer;
wherein the insulating layer is disposed between the first metal layer and the second metal layer, the first metal layer has portions defining a first cavity, the insulating layer has portions defining a second cavity and a provisional region, the first cavity has a width larger than a width of the second cavity, and the provisional region is defined by a sidewall of the first metal layer defining the first cavity and a sidewall of the insulating layer defining the second cavity.
applying a first masking layer covering the first metal layer and the provisional region and exposing the second cavity;
electroplating a heat dissipating metal member in the second cavity; and
removing the first masking layer.

2. The circuit board structure manufacturing method as recited in claim 1, wherein in the step of providing a circuit board, the first and second cavities are formed by the steps comprising:
developing a pattern on the first metal layer to form the first cavity; and
forming the second cavity through the insulating layer and exposing the second metal layer.

3. The circuit board structure manufacturing method as recited in claim 2, wherein the step of developing a pattern on the first metal layer comprises the step of:
laser-ablating the first metal layer to form the first cavity thereon.

4. The circuit board structure manufacturing method as recited in claim 1 further comprising the step of:
abrasively treating the heat-dissipating metal member to flatten a top portion thereof.

5. The circuit board structure manufacturing method as recited in claim 1, wherein the first masking layer is formed after the second cavity is formed and the first masking layer covers the first metal layer and the first cavity.

6. The circuit board structure manufacturing method as recited in claim 1 wherein the first masking layer is formed before the second cavity is formed and the first masking layer covers the first metal layer and the first cavity.

7. The circuit board structure manufacturing method as recited in claim 4, wherein the top portion of the heat-dissipating metal member and the first metal layer are leveled.

8. The circuit board structure manufacturing method as recited in claim 4, wherein the top portion of the heat-dissipating metal member is lower in height than the insulating layer.

9. The circuit board structure manufacturing method as recited in claim 1 further comprising the step of:
disposing an electronic component on and coupled to the heat-dissipating metal member, wherein the electronic component is electrically connected to the first metal layer.

10. The circuit board structure manufacturing method as recited in claim 1 further comprising the step of:
forming a second masking layer covering the second metal layer.

11. The circuit board structure manufacturing method as recited in claim 1, wherein the second cavity is formed by laser-ablating the insulating layer.

12. A circuit board structure, comprising:
a circuit substrate including an insulating layer, a first metal layer, and a second metal layer, wherein the insulating layer is disposed between the first metal layer and the second metal layer, the first metal layer has portions defining a first cavity, the insulating layer has portions defining a second cavity, the second cavity is exposed through the second metal layer, and the first cavity has a width larger than a width of the second cavity; and
at least one heat-dissipating metal member formed in the second cavity.

13. The circuit board structure manufacturing method as recited in claim 12, wherein the insulating layer has a provisional region defined by a sidewall of the first metal layer defining the first cavity and a sidewall of the insulating layer defining the second cavity.
